(19) United States
(12) Patent Application Publication
(10) Pub. No.: US 2013/0100622 A1
(43) Pub. Date: Apr. 25, 2013

(54) ELECTRONIC DEVICE AND FASTENING STRUCTURE FOR CIRCUIT BOARD

(71) Applicants: YUAN-MING WANG, Shenzhen City (CN); NA WANG, Shenzhen City (CN); JIAN-YONG YANG, Shenzhen City (CN); YUN WANG, Shenzhen City (CN)

(72) Inventors: YUAN-MING WANG, Shenzhen City (CN); NA WANG, Shenzhen City (CN); JIAN-YONG YANG, Shenzhen City (CN); YUN WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/527,815

(22) Filed: Jun. 20, 2012

(30) Foreign Application Priority Data
Oct. 19, 2011 (CN) 201120398743.0

(51) Int. Cl. H05K 5/02

(52) U.S. Cl. 361/759

(57) ABSTRACT

A fastening structure for fastening a circuit board, includes a loading member, a holding member, and a fixing member. The loading member is positioned inside of an electronic device. The holding member protrudes from the loading member. The fixing member protrudes from the loading member. When the circuit board is fastened, the holding member presses on the circuit board, and the fixing member passes through a fixing hole define in the circuit board, so as to restrict the circuit board to move in a first plane parallel to the circuit board, and a second plane perpendicular to the circuit board.

### BACKGROUND

1. Technical Field

The present disclosure relates to electronic devices, and particularly to an electronic device and a fastening structure for fastening circuit boards to the device.

2. Description of Related Art

Electronic devices include circuit boards. The circuit boards are commonly fastened on an inner side of the housings of the electronic devices with many screws, which makes the assembly and disassembly of the circuit boards more difficult.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of an inner structure of an electronic device.

FIG. 2 is an exploded view of the electronic device in FIG. 1.

FIG. 3 is a view of a circuit board being assembled to the electronic device in FIG. 2.

### DETAILED DESCRIPTION

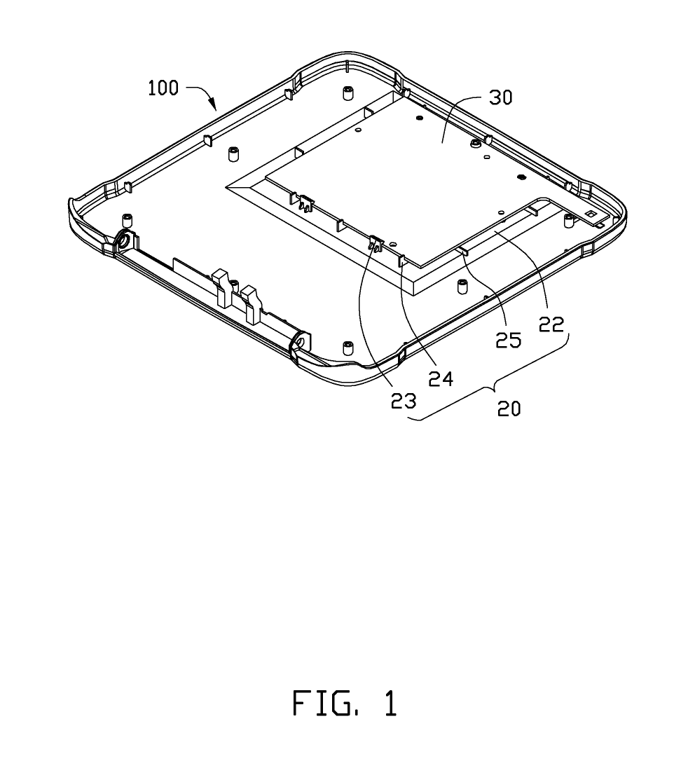

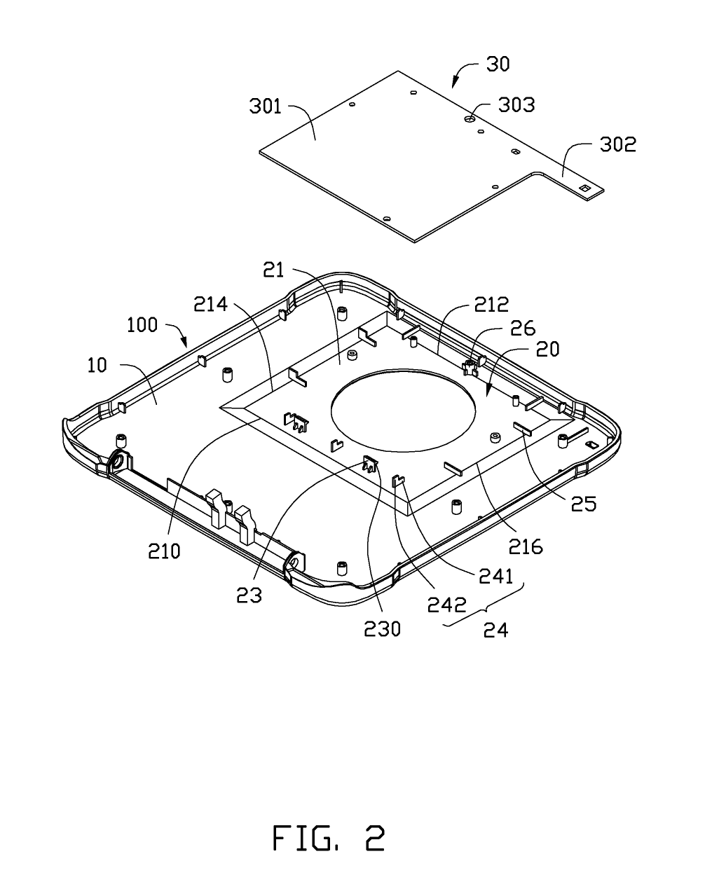

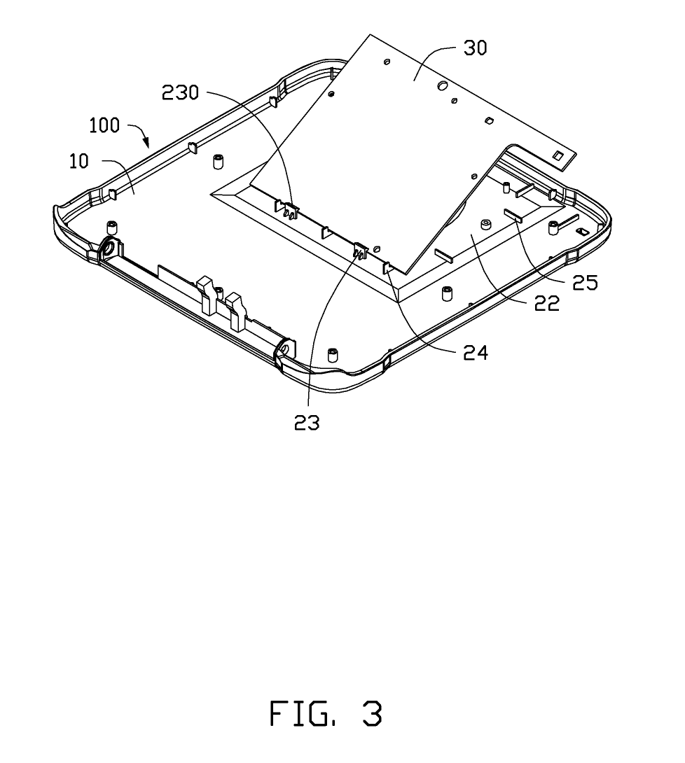

Referring to FIGS. 1-3, the electronic device 100 includes a housing 10, a fastening structure 20 located inside the housing 10, and a circuit board 30 fastened by the fastening structure 20. The circuit board 30 includes a board 301 and a narrow extension 302 extending from a corner of the board 301. The board 301 defines a fixing hole 303.

The fastening structure 20 includes a loading member 22 protruding from the housing 10, a plurality of holding members 23, a plurality of blocking members 24, a plurality of balancing members 25, and a plurality of fixing member 26. The holding members 23, the blocking members 24, the balancing members 25, and the fixing members 26 protrude from the loading member 22.

The loading member 22 includes a square loading surface 21 away from the housing 10. The four edges of the square loading surface 21 are called a first edge 210, a second edge 212 opposite to the first edge 210, a third edge 214, and a fourth edge 216 opposite to the third edge 214.

The holding members 23 are positioned at the loading surface 21 at intervals, and arranged in a line adjacent to the first edge 210. In this embodiment, there are two holding members 23. Each holding member 23 includes a hook 230 on its end away from the loading surface 21

The blocking members 24 are positioned on the loading surface 21. There are five blocking members 24. Three of the blocking members 24 are adjacent to the first edge 210, the other two blocking members 24 are adjacent to the third edge 214. The three blocking members 24 adjacent to the first edge 210 are arranged so that each holding member 23 is positioned between two blocking members 24. The blocking members 24 are L shaped. The blocking members 24 each include a supporting part 241 protruding from the loading surface 21, and a blocking part 242 extending from the supporting member 241.

The balancing members 25 protrude from the loading surface 21. In this embodiment, there are four balancing members 25. Two of the balancing members 25 are adjacent to the second edge 212, the other two of the balancing members 25 are adjacent to the fourth edge 216. The height of the balancing members 25 is the same as the height of the supporting members 241.

The fixing member 26 protrudes from the loading surface 21, and corresponds to the fixing hole 303.

In assembly, first, the circuit board 30 is aligned over the loading surface 21, with the extension 302 extending from the fourth edge 216. Then the side of the circuit board 30 corresponding to the first edge 210 is inclined to the loading surface 21 and positioned below the hooks 230. Finally, the circuit board 30 is completely lowered into place and the remaining sides of the board 301 abut against the blocking parts 242. The fixing member 26 extends through the fixing hole 303, thus, the circuit board 30 is held in place.

It is to be understood, however, that even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A fastening structure for fastening a circuit board of an electronic device, the fastening structure, comprising:
a loading member positioned inside of the electronic device;
a holding member protruding from the loading member; and
a fixing member protruding from the loading member;
wherein when the circuit board is fastened, the holding member presses the circuit board, and the fixing member passes through a fixing hole define in the circuit board, so as to restrict the circuit board to move in a first plane parallel to the circuit board, and a second plane perpendicular to the circuit board.

2. The fastening structure of claim 1, wherein the loading member comprises a first edge and a second edge connected to the first edge, the holding member protrudes from the first edge; the fastening structure further comprises two blocking members, one blocking member protrudes from the first edge, the other blocking member protrudes from the second edge, the two blocking members restrict against two sides of the circuit board in two directions to orient the circuit board before the circuit board being pressed by the holding member.

3. The fastening structure of claim 2, wherein the blocking member comprises a supporting part protruding from the loading member, and a blocking part protruding from the supporting part, the supporting part supports the circuit board, the blocking part restrict against the circuit board.

4. The fastening structure of claim 3, wherein the loading member further comprises a third edge parallel to the first edge, and a fourth edge parallel to the second edge, the fastening structure further comprises two balancing members, two balancing members protrude from the third and the fourth edges, respectively, the height of the balancing members are the same as the height of the supporting member.

5. An electronic device comprising
a circuit board defining a fixing hole; and
a fastening structure comprising:
a loading member positioned inside of the electronic device,
a holding member protruding from the loading member; and
a fixing member protruding from the loading member;
wherein when the circuit board is fastened, the holding member presses the circuit board, and the fixing member passes through the fixing hole, so as to restrict the circuit board to move in a first plane parallel to the circuit board, and a second two plane perpendicular to the circuit board.

6. The electronic device of claim 5, wherein the loading member comprises a second edge connected to the first edge, the fastening structure further comprises two blocking member, one blocking member protrudes from the first edge, the other blocking member protrudes from the second edge, the two blocking members restrict against two sides of the circuit board in two directions to orient the circuit board before the circuit board is hooked by the holding member.

7. The electronic device of claim 6, wherein the blocking member comprises a supporting part protruding from the loading member, and a blocking part protruding from the supporting part, the supporting part supports the circuit board, the blocking part restricts against the circuit board.

8. The electronic device of claim 7, wherein the loading member further comprises a third edge parallel to first edge, and a fourth edge parallel to the second edge, the fastening structure further comprises two balancing members, two balancing members protrude from the third and the fourth edges, respectively, the height of the balancing members are the same as the height of the supporting member.

9. A fastening structure for fastening a circuit board, the fastening structure, comprising:
a loading member positioned inside of an electronic device, the loading member comprise a first edge and a second edge connected to the first edge;
a holding member protruding from the first edge, the holding member comprising a hook; and
two blocking members protruding from the first edge and the second edge respectively;
wherein the blocking members restrict against two sides of the circuit board in two directions to orient the circuit board, the hook fastens the circuit board after the circuit board is oriented.

10. The fastening structure of claim 9, wherein each the blocking member comprises a supporting part protruding from the loading member, and a blocking part protruding from the supporting part, the supporting part supports the circuit board, the blocking part restricts against the circuit board.

11. The fastening structure of claim 10, wherein the loading member further comprises a third edge parallel to first edge, and a fourth edge parallel to the second edge, the fastening structure further comprises two balancing members, the two balancing members protrude from the third and the fourth edges, respectively, the height of the balancing members are the same as the height of the supporting member.
